(19) United States
(12) Patent Application Publication
(10) Pub. No.: US 2013/0025531 A1
(43) Pub. Date: Jan. 31, 2013

(54) METHODS FOR MODIFYING CRYSTALLOGRAPHIC SYMMETRY ON THE SURFACE OF A SILICON WAFER

(71) Applicant: MICHAEL A. CAPANO, West Lafayette, IN (US)

(72) Inventor: MICHAEL A. CAPANO, West Lafayette, IN (US)

(21) Appl. No.: 13/331,427

(22) Filed: Dec. 20, 2011

Related U.S. Application Data
(60) Provisional application No. 61/511,161, filed on Jul. 25, 2011.

(51) Int. Cl. C30B 25/18

(52) U.S. Cl. 117/95

(57) ABSTRACT

A method for modifying crystallographic symmetry on the surface of a silicon (001) wafer, the method comprising providing a silicon substrate wafer having a symmetry element, forming a symmetry breaking layer on the substrate, and growing at least one transformation layer having a 3-fold or 6-fold rotational symmetry axis substantially perpendicular to the wafer surface on the formed symmetry breaking layer.

### CROSS-REFERENCE TO RELATED APPLICATIONS

This application is related and claims priority to U.S. Provisional Patent Application Ser. No. 61/511,161, which was filed on Jul. 25, 2011. The complete and entire disclosure for this application is hereby expressly incorporated herein by this reference.

### TECHNICAL FIELD

The present invention generally relates to the growth of materials possessing hexagonal symmetry, or materials possessing cubic symmetry, to be grown on the (001) orientated surface of silicon, and particularly where the orientation of the grown crystalline material is such that the (0001) basal planes of the hexagonal material are substantially parallel to the (001) atomic planes of silicon, or the (111) planes of the grown cubic material are substantially parallel to the (001) atomic planes of silicon.

### BACKGROUND OF THE INVENTION

A general precept of epitaxial growth is that the structural characteristics of a grown layer (e.g. orientation, lattice parameter) are determined by the underlying substrate characteristics. As such, it is often the case that the symmetry of the grown overlayer takes on the symmetry of the substrate. This general precept is the reason why growth of basal-plane (0001) orientated hexagonal materials (with 3-fold or 6-fold rotational symmetry), or (111) orientated cubic materials onto silicon (001) substrates with 4̅ (i.e. “4 bar”) is difficult and leads to high concentrations of crystalline defects as the overlayer attempts to match the symmetry of the substrate. Traditional solutions for the growth of III-nitride epilayers with (0001) orientation substantially parallel to the surface involve growth on sapphire, zinc oxide and silicon carbide. Recent reports have shown a trend towards III-nitride growth on silicon substrates. Nitride epitaxy on silicon is predominantly done using Si (111) oriented substrates. Growth on Si (001) substrates is preferred because it is the orientation used in the Si CMOS industry, which would facilitate integration of III-nitrides or graphene technology with Si electronics. Other reasons for the preference of Si (001) over Si (111) are lower defect densities in (001), Si (001) is easier to cleave, and unit-step processes are better established on Si (001).

There is need to develop a means of achieving growth of hexagonal materials with basal-plane orientation or cubic materials with (111) orientation onto Si (001) substrates. Such a system could be compatible with the high-volume production of wafers, and unlike some conventional techniques, could be performed without requiring the patterning of the substrate surface prior to achieving the growth.

The present invention is intended to improve upon and resolve some of these known deficiencies within the relevant art.

### SUMMARY OF THE INVENTION

The present invention relates to the growth of materials possessing hexagonal symmetry, or materials possessing cubic symmetry, to be grown on the (001) orientated surface of silicon, and particularly where the orientation of the grown crystalline material is such that the (0001) basal planes of the hexagonal material are substantially parallel to the (001) atomic planes of silicon, or the (111) planes of the grown cubic material are substantially parallel to the (001) atomic planes of silicon. The invention further relates to the range of orientations of the silicon substrate, where all misorientations of the silicon (001) substrate wafer less than or equal to 10 degrees can accommodate growth of basal plane hexagonal materials or (111) orientated cubic materials. The present invention has many applications, including but not limited to the growth of III-nitride materials for light-emitting diode (LED) applications; growth of III-nitride materials for lateral rf-device architectures; growth of carbon-based graphene materials for electronic, transparent contacts and sensing applications; growth of wide-bandgap silicon-carbide (SiC) for high-temperature sensing and lateral power devices; and growth of silicon carbide as a template for subsequent III-nitride growth for the above-mentioned applications.

According to one aspect of the present invention, a method for modifying the crystallographic symmetry on the surface of a silicon wafer, having a surface substantially orientated parallel to the (001) crystallographic plane, by depositing materials onto the surface that produce a surface with hexagonal symmetry is provided. According to these specific embodiments, nonmetallic materials are used to yield a surface having a 3-fold or 6-fold rotational symmetry that is suitable for the subsequent growth of materials possessing 3-fold or 6-fold rotational symmetry. As the implementation of this concept in a real material requires using transition materials, the concept of symmetry transformation layers (STL) as used herein is intended to illustrate how the symmetry of a Si (001) surface is transformed from one set of symmetry elements to another set.

In accordance with yet another aspect of the present invention, a method for modifying crystallographic symmetry on the surface of a silicon (001) wafer comprises providing a silicon substrate wafer having a symmetry element, forming a symmetry breaking layer on the substrate, and growing at least one transformation layer having a 3-fold or 6-fold rotational symmetry axis substantially perpendicular to the wafer surface on the formed symmetry breaking layer.

According to another embodiment of the present invention, a method for modifying crystallographic symmetry on the surface of a silicon (001) wafer comprises providing a silicon (001) substrate having a 4̅ (i.e. 4 bar) rotational symmetry element, forming a symmetry breaking layer on the substrate to break the 4̅ rotational symmetry of the underlying silicon (001) substrate, analyzing the formed symmetry breaking layer, and depositing at least one transformation layer having a 3-fold or 6-fold rotational symmetry axis substantially perpendicular to the silicon (001) substrate on the symmetry breaking layer.

### BRIEF DESCRIPTION OF THE DRAWINGS

The above-mentioned aspects of the present invention and the manner of obtaining them will become more apparent and the invention itself will be better understood by reference to the following description of the embodiments of the invention taken in conjunction with the accompanying drawings, wherein:

FIG. 1 is a schematic illustration of a hexagonal crystalline layer, with direction normal to surface, grown on a Si (001) surface using a symmetry transformation layer in accordance with the teachings of the present invention;

FIG. 2 is a flowchart showing an illustrative symmetry transformation layer (STL) process in accordance with the teachings of the present invention; and

FIG. 3 is a graphical representation of X-ray diffraction data from a 3C-SiC epilayer grown on Si (001) substrate with an intermediate symmetry transformation layer (STL) in accordance with the teachings of the present invention.

Corresponding reference characters indicate corresponding parts throughout the several views. Although the exemplification set out herein illustrates embodiments of the invention, in several forms, the embodiments disclosed below are not intended to be exhaustive or to be construed as limiting the scope of the invention to the precise forms disclosed.

### DETAILED DESCRIPTION

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

Unless defined otherwise, all technical and scientific terms used herein have the same meaning as commonly understood by one of ordinary skill in the art to which this invention belongs. Although any method and materials similar or equivalent to those described herein can be used in the practice or testing of the present invention, the specific methods and materials are now described.

All references mentioned hereunder are incorporated by reference in their entirety. Unless mentioned otherwise, the techniques employed or contemplated herein are standard methodologies well known to one of ordinary skill in the art and the materials, methods and examples are illustrative only and not intended to be limiting.

In accordance with certain aspects of the present invention, nonmetallic materials can be used to affect a change in the symmetry of atomic arrangements on the surface of a substrate. This symmetry transformation necessary for the growth of hexagonal crystals, such as Group III nitrides, SiC and graphene, requires the creation of a surface having 3-fold or 6-fold rotational symmetry. Implementation of this concept in real materials requires using transition materials, and the concept of symmetry transformation layers (STL) is developed to prepare a substrate surface for hexagonal crystal growth or deposition with its basal plane (0001) substantially parallel to the surface, or the growth of cubic crystals with its (111) planes substantially parallel to the surface.

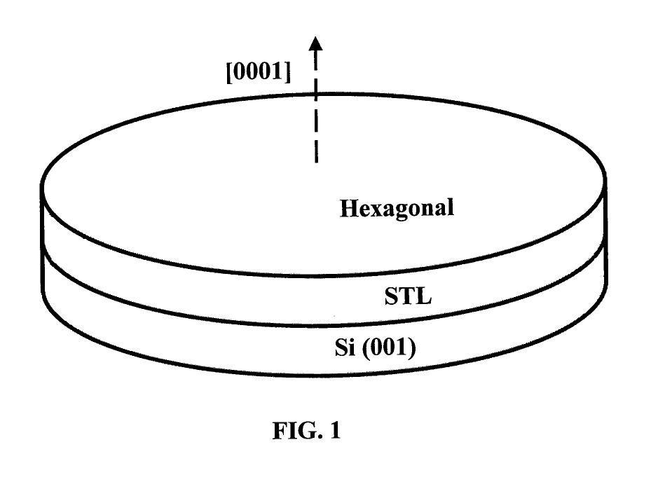

FIG. 1 illustrates the concept of using symmetry transformation layers for the growth of a crystalline layer possessing 3-fold or 6-fold rotational symmetry element substantially perpendicular to the substrate. In accordance with certain aspects of the present invention, the STL may be comprised of one or more materials. The first step in constructing the STL, according to certain aspects of the present invention, is to break the 4̅ (i.e. 4 “bar”) rotational symmetry of the underlying Si (001) substrate. It should be understood and appreciated herein that the successful breaking of the underlying substrate symmetry may be achieved in various ways. In accordance with one aspect of the present invention, an amorphous or polycrystalline material of sufficiently small grain size can be employed, including a deposited or thermally-grown Si-oxide (SiO₂). Growth of subsequent nominally single-crystalline or highly textured material exploits the material's tendency to minimize its surface free energy by crystallizing with its basal planes (0001) [for hexagonal crystal] or its close-packed (111) planes [for cubic crystals] substantially parallel to the substrate surface. There is no exposure to an underlying symmetry element to control the orientation of growth domains with respect to rotation about an axis perpendicular to the surface, and random rotational disorder could be expected depending on the kinetics associated with the growth conditions. To achieve better control over rotational disorder of domains on the growth surface, in accordance with certain illustrative embodiments of the present invention, the growth of an initial crystalline layer can be performed to exploit specific crystallographic relationships (e.g. Si₃N₄ [1 1̅ 00]∥Si [100]). Such a process greatly aids in aligning the epitaxial layer with respect to rotational order while permitting crystallization with (0001) basal planes (hexagonal materials) or (111) close-packed planes (cubic materials) substantially parallel to the surface.

Following the formation of a symmetry-breaking layer, one or more transition layers are grown or deposited onto the symmetry-breaking layers. The last of these layers is selected to have 3-fold or 6-fold rotational symmetry, which enables subsequent growth of materials having 3-fold or 6-fold rotational symmetry, including hexagonal crystals. Subsequently grown layers are represented in the figure as “Hexagonal” with the direction perpendicular to the basal plane, [0001], shown perpendicular to the surface. In this particular instance, the use of the term “Hexagonal” exemplarily in the figure is not intended to suggest this embodiment of the invention does not apply to cubic materials growing with (111) planes substantially parallel to the surface. Other transition layers which precede the final transition layer serve the purpose of facilitating deposition of the final layer, or improving the crystalline quality of the final layer, or both. In the end, a Si (001) substrate having a surface with 3-fold or 6-fold rotational symmetry that can be used as a template for the growth of hexagonal materials, or other 3-fold or 6-fold rotational materials (e.g. cubic materials with (111) planes substantially parallel to the surface), is produced.

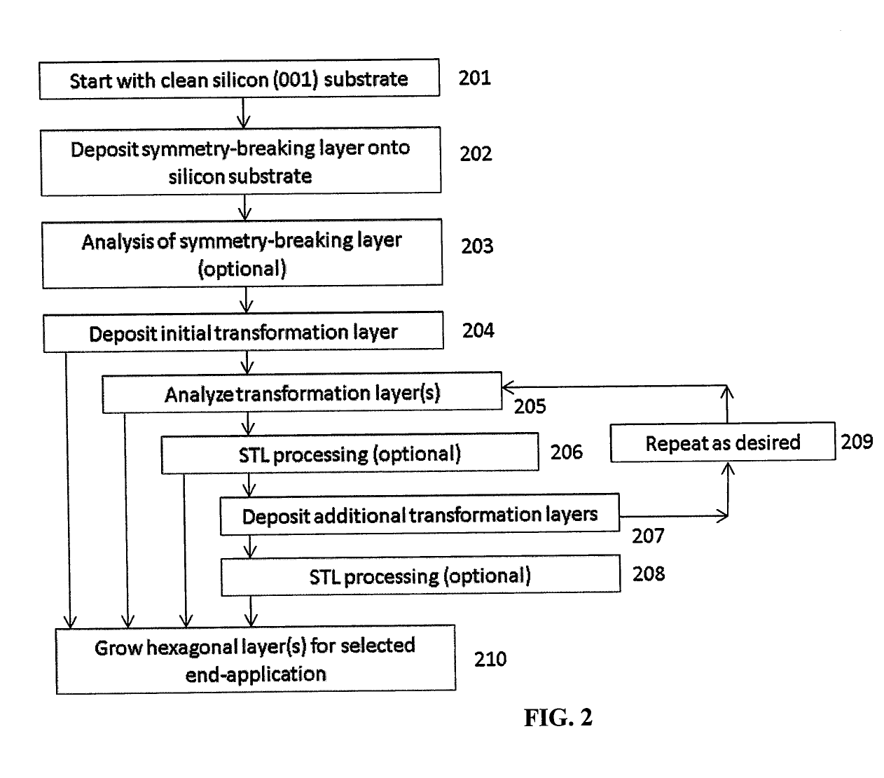

FIG. 2 illustrates an exemplary symmetry transformation layer (STL) process in accordance with the teachings of the present invention. The first step of this process involves providing a clean silicon (001) substrate (step 201). In accordance with this illustrative embodiment, the substrate is a Si (001) orientated wafer. It should be understood and appreciated herein that while there are no limitations on the lateral dimensions or thickness of the starting material, and no limitations on the shape of the starting material, in accordance with certain embodiments, the substrate diameters may be greater than or equal to 50 mm, and the substrate thickness may be greater than or equal to 450 micrometers. Wafers precisely cut on the (001) orientation, or wafers misorientated by up to and including 10 degrees from the (001) orientation, are suitable for STL processing. It should be understood and appreciated herein that standard cleaning procedures commonly practiced within the semiconductor industry are compatible with this invention.

The next step in the process includes depositing a symmetry-breaking layer onto the silicon substrate (step 202). The initial symmetry-breaking layer grown onto the substrate is chosen based on the end application. For instance, one embodiment of this invention is to grow a silicon-nitride layer by plasma-enhanced chemical vapor deposition (PECVD) directly on the Si substrate. In accordance with this illustrative embodiment, optimal growth conditions may include the following: a temperature within the range of from about 250° C. to about 700° C., and particularly about 400° C.; a pressure within the range of from about 100 mTorr to about 1000 mTorr, particularly about 400 mTorr; an ammonia flow rate within the range of from about 20 sccm to about 200 sccm, particularly about 100 sccm; and a 5% dichlorosilane/hydrogen flow rate in the range of from about 20 sccm to about 200 sccm, particularly about 120 sccm. Growth thickness is controlled by time and can vary up to 100 nm or thicker, with the ultimate limitation on thickness being imposed by the formation of cracks in the deposited nitride layer. Another embodiment would be to grow a SiO₂ layer thermally to completely remove the influence of the underlying substrate symmetry. An oxide has the advantage of isolating the grown overlayers electronically from the substrate. Industry standard oxidation procedures are adequate for this purpose. An oxidation in wet O₂ ambient at 1100° C. for 1 hour yields an oxide approximately 600 nm thick and would be suitable for the STL process. Other growth conditions (e.g., dry v. wet O₂; temperature range of from about 950° C. to about 1200° C.) consistent with industrial practices are adequate for this purpose, and it should be understood and appreciated herein that there is no upper limitation on oxide thickness imposed by the teachings of the present invention.

The next step in the process involves optionally analyzing the symmetry-breaking layer (i.e., general assessment of the structural integrity of the symmetry-breaking layer) during process development or quality assurance runs (step 203). If a crystalline symmetry-breaking layer is initially employed, the crystallite size and orientation can be determined using x-ray diffraction methods. Measurement of surface roughness using scanning probe microscopy (SPM) or other techniques, and measurement of the electrical properties and thickness are suggested for initial process development. Following completion of the optional characterization of the symmetry-breaking layer(s), the initial transformation layer is grown (step 204). The chosen material for this step can vary widely, depending on the end application. In accordance with certain aspects of the present invention, a silicon-nitride layer can be used, but it should be understood and appreciated herein that other nitrides (e.g. AlN) or crystalline oxides (e.g. hafnium oxide) can be used for this step without straying from the teachings of the present invention. It should also be understood and appreciated herein that step 204 can be effective using any materials that permit the formation of a nominally single-crystalline or highly-textured material possessing a 3-fold or 6-fold rotational symmetry element that lies substantially perpendicular to the surface of the substrate. To this end, the selection of the material used in step 204 is strongly influenced by the final materials the end-application requires for operation. For example, if III-nitride layers are desired for construction of a field-effect transistor, then aluminum nitride would be an acceptable selection for a transition layer. If a process has been established, then growth of the final device layer can be done without intermediate transformation layer growth or characterization.

Development of new growth processes or measurements to ensure quality of growth structures may require intermediate steps (i.e., steps 205 and 206). Step 205 involves the analysis of the transformation layers for crystal quality and orientation evaluation to provide feedback useful for improving the initial transformation layers in future runs. This analysis can be performed using x-ray diffraction, surface roughness measurements using SPM, as well as other general analytical evaluations (e.g. scanning electron microscopy, optical microscopy, x-ray photoelectron spectroscopy). Step 206 involves performing post-processing techniques on the initial transformation layers if desired. Such post-processing techniques may include smoothing the surface by chemomechanical polishing, patterning the surface for subsequent selective growth, and performing ion implantation to control electrical characteristics of the transformation layers, or to deposit structures to be embedded into the transformation stack (e.g. to tailor the mechanical or optical properties of the STL).

Once the initial symmetry transformation layer is complete, subsequent layer growth (step 207), as well as analysis and post-processing steps (step 208) may optionally be employed to tailor the properties of the STL and the final device material. STL layer growth, analysis and post-processing can be repeated as many times as necessary to optimize a growth process (step 209). Upon completion of STL growth, device layer(s) may be grown (step 210); however, it should be understood and appreciated herein that users have the option of moving directly to this step at any point in the process flow.

Advantages and improvements of the processes, methods and compositions of the present invention are demonstrated in the following example. This example is illustrative only and is not intended to limit or preclude other embodiments of the present invention.

### Example 1

To test the STL concept, a silicon carbide (SiC) epilayer was grown on a Si (001) substrate using silicon nitride transformation layers. In this example, the initial symmetry-breaking silicon nitride layer was grown using PECVD to a thickness of 100 nm. Analysis of the grown layer showed good surface morphology (rₘₛ≈0.5 nm), but x-ray diffraction indicated high stresses present in the layer. A second layer of silicon nitride was deposited using low-pressure chemical vapor deposition (LPCVD) using the following conditions: temperature: 800° C., pressure: 300 mTorr, ammonia flow rate: 100 sccm, dichlorosilane flow rate: 80 sccm, thickness: 100 nm. Film stresses were significantly reduced and there was no evidence of cracking in the layer. Growth of SiC on the nitride STL was done under the following conditions: temperature: 1200° C.; pressure: 100 mbar; H₂ flow rate: 30 slm; propane flow rate: 3 sccm; and silane flow rate: 6 sccm.

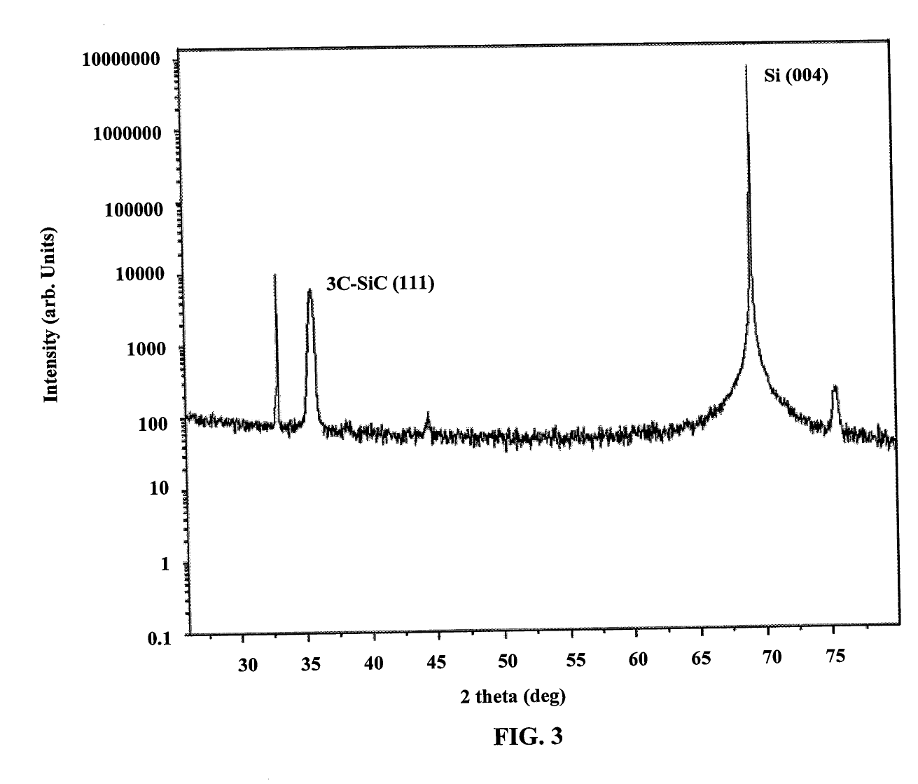

Typically, SiC grown on a Si (001) surface form the 3C polytype (which has a cubic lattice) with its (001) crystallographic planes orientated parallel to the surface. In the present example, successful conversion of the surface to one having 3-fold rotational symmetry is confirmed by x-ray diffraction data, shown in FIG. 3. The θ-2θ geometry used to collect the data in FIG. 3 only detects diffraction from atomic planes that are parallel to the surface. Peaks corresponding to the (004) reflection from Si and the (111) reflection from 3C-SiC are present in the same scan. There is no evidence of a SiC (004) reflection which would be expected if the STL between Si (001) substrate and SiC layer were not present. Therefore, the surface symmetry has been converted from 4̅ to 3-fold rotational symmetry ideally suited for the growth of a 3-fold symmetric material [note: 3C-SiC is a cubic material, not a hexagonal material, but the (111) planes now parallel to the surface exhibit 3-fold rotational symmetry]. Growth of graphene, which possesses a hexagonal lattice structure, has also been successfully grown on Si (001) using this invention.

While an exemplary embodiment incorporating the principles of the present invention has been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

### REFERENCES

The following references are incorporated herein by reference in their entirety:
1. Morkoç, H.; Strite, S.; Gao, G. B.; Lin, M. E.; Sverdlov, B.; Burns, M. (1994). “Large-band-gap SiC, III-V nitride, and II-VI ZnSe-based semiconductor device technologies”. Journal of Applied Physics 76 (3): 1363 (1994).
2. New Journal of Physics 9 (2007) 389 (http://www.nip.org/).
3. F. Schulze, A. Dadgar and A. Krost, Epitaxial Group III Nitride Layer on (001)-oriented Group IV Semiconductor, Patent No.: U.S. Pat. No. 7,935,987 B2, May 3, 2011.
4. Jaeger, Richard C. (2001). “Thermal Oxidation of Silicon”. Introduction to Microelectronic Fabrication. Upper Saddle River: Prentice Hall. ISBN 0-201-44494-1.

What is claimed is:

1. A method for modifying crystallographic symmetry on the surface of a silicon (001) wafer, the method comprising:
providing a silicon substrate wafer having a symmetry element;
forming a symmetry breaking layer on the substrate; and
growing at least one transformation layer having a 3-fold or 6-fold rotational symmetry axis substantially perpendicular to the wafer surface on the formed symmetry breaking layer.

2. The method of claim 1, wherein the step of growing at least one transformation layer on the formed symmetry breaking layer includes depositing a silicon-nitride layer on the symmetry breaking layer.

3. The method of claim 2, wherein the step of depositing a silicon-nitride layer on the symmetry breaking layer comprises using plasma-enhanced chemical vapor deposition (PECVD) to grow the silicon-nitride layer directly on the silicon substrate wafer.

4. The method of claim 1, wherein the step of forming a symmetry breaking layer on the substrate includes depositing an oxide on the substrate.

5. The method of claim 1, wherein the at least one transformation layer having a 3-fold or 6-fold rotational symmetry axis substantially perpendicular to the wafer surface is the final transformation layer within a series of transformation layers.

6. The method of claim 1, wherein misorientations of the silicon substrate wafer less than or equal to 10 degrees are adapted to accommodate growth of basal plane hexagonal materials or (111) orientated cubic materials.

7. The method of claim 1, wherein the step of forming a symmetry breaking layer on the substrate includes breaking the 4̅ rotational symmetry of the underlying silicon substrate wafer.

8. The method of claim 7, wherein the step of breaking the 4̅ rotational symmetry of the underlying silicon substrate wafer includes employing an amorphous or polycrystalline material of sufficiently small grain size.

9. The method of claim 8, wherein the step of employing an amorphous or polycrystalline material of sufficiently small grain size includes employing a deposited or thermally-grown Si-oxide (SiO₂).

10. The method of claim 1, further comprising analyzing the formed symmetry breaking layer with at least one of an x-ray diffraction method and a scanning probe microscopy technique.

11. The method of claim 1, wherein the step of growing at least one transformation layer on the formed symmetry breaking layer includes depositing an aluminum nitride layer on the symmetry breaking layer.

12. A method for modifying crystallographic symmetry on the surface of a silicon (001) wafer, the method comprising:
providing a silicon (001) substrate having a 4̅ rotational symmetry element;
forming a symmetry breaking layer on the substrate to break the 4̅ rotational symmetry of the underlying substrate;
analyzing the formed symmetry breaking layer; and
depositing at least one transformation layer having a 3-fold or 6-fold rotational symmetry axis substantially perpendicular to the silicon (001) substrate on the symmetry breaking layer.

13. The method of claim 12, wherein the step of depositing at least one transformation layer comprises depositing a silicon-nitride layer on the symmetry breaking layer.

14. The method of claim 13, wherein the step of depositing a silicon-nitride layer on the symmetry breaking layer comprises using plasma-enhanced chemical vapor deposition (PECVD) to grow the silicon-nitride layer directly on the silicon (001) substrate.

15. The method of claim 12, wherein the step of forming a symmetry breaking layer on the substrate includes depositing an oxide on the substrate.

16. The method of claim 12, wherein misorientations of the silicon (001) substrate less than or equal to 10 degrees are adapted to accommodate growth of basal plane hexagonal materials or (111) orientated cubic materials.

17. The method of claim 12, wherein the step of breaking the 4̅ rotational symmetry of the underlying silicon (001) substrate includes employing an amorphous or polycrystalline material of sufficiently small grain size.

18. The method of claim 17, wherein the step of employing an amorphous or polycrystalline material of sufficiently small grain size includes employing a deposited or thermally-grown Si-oxide (SiO₂).

19. The method of claim 12, further comprising analyzing the formed symmetry breaking layer with at least one of an x-ray diffraction method and a scanning probe microscopy technique.

20. The method of claim 12, wherein the step of depositing at least one transformation layer includes depositing an aluminum nitride layer on the symmetry breaking layer.
